(19) United States
(12) Patent Application Publication
(10) Pub. No.: US 2026/0309826 A1
(43) Pub. Date: Oct. 8, 2026

(54) TEST AND/OR MEASUREMENT SYSTEM

(71) Applicant: Rohde & Schwarz GmbH & Co. KG, Muenchen (DE)

(72) Inventor: Markus FREIDHOF, Muenchen (DE)

(21) Appl. No.: 19/539,842

(22) Filed: Feb. 13, 2026

(30) Foreign Application Priority Data
Apr. 8, 2025 (DE) 10 2025 113 778.1

(51) Int. Cl. G01R 35/00; G01R 27/32; G01R 31/11; G01R 31/28; G01R 31/3167; G01R 31/317

(52) U.S. Cl. CPC G01R 35/005; G01R 27/32; G01R 31/11; G01R 31/2834; G01R 31/3167; G01R 31/31725

(57) ABSTRACT

A system comprises a signal parameter circuit configured to provide at least one digital signal parameter, wherein the at least one digital signal parameter comprises a frequency of an analog test signal to be generated. The system comprises a signal generator circuit connected to the signal parameter circuit, wherein the signal generator circuit is configured to generate the analog test signal based on the at least one digital signal parameter. The signal parameter circuit is configured to successively adjust the frequency of the analog test signal across a first frequency band by the at least one generated digital signal parameter, so that the analog test signal has a frequency sweep across the first frequency band. A first measurement circuit is configured to evaluate a portion of the analog test signal and a first measurement signal during the frequency sweep across the first frequency band with an unchanging first frequency conversion.

### CROSS-REFERENCE(S) TO RELATED APPLICATION(S)

This application claims priority to German Application No. 10 2025 113 778.1, filed on Apr. 8, 2025, the entire disclosure of which is enclosed herein in its entirety.

### FIELD OF THE DISCLOSURE

Embodiments of the present disclosure generally relate to a test and/or measurement system for performing tests and/or measurements on a device under test.

### BACKGROUND

The use of vector network analyzers (VNA) is an essential part of the characterization and analysis of high-frequency (HF) and microwave components. Traditionally, these systems are based on the use of analog oscillators, which provide frequency adjustment and correct signal levels. However, these oscillators require a certain settling time before accurate measurements can be made, which leads to longer overall measurement times, especially for frequency sweeps.

Thus, there is a need for a test and/or measurement system that allows faster measurements on a device under test.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a test and/or measurement system for performing tests and/or measurements on a device under test. In an embodiment, the test and/or measurement system comprises a signal parameter circuit that is set up to provide at least one digital signal parameter. The at least one digital signal parameter comprises, for example, a frequency of an analog test signal to be generated. The test and/or measurement system also comprises a signal generator circuit connected to the signal parameter circuit. The signal generator circuit is set up to generate the analog test signal based on the at least one digital signal parameter.

The test and/or measurement system has at least one first port connected to the signal generator circuit. The first port is adapted to be connected to the device under test. The test and/or measurement system also has a first coupling circuit arranged between the signal generator circuit and the first port. The test and/or measurement system further has a first measurement circuit connected to the first coupling circuit. The first measurement circuit has a first analog-to-digital converter. The first measurement circuit is set up to evaluate a portion of the analog test signal and a first measurement signal received via the first port. The signal parameter circuit is set up to successively adjust the frequency of the analog test signal across a first frequency band by the at least one generated digital signal parameter so that the analog test signal has a frequency sweep across the first frequency band. The first measurement circuit is set up to evaluate the portion of the analog test signal and the first measurement signal received via the first port during the frequency sweep across the first frequency band with an unchanging first frequency conversion.

The term “frequency conversion” means that the respective signal is mixed with a local oscillator signal to convert the frequency of the respective signal into a baseband suitable for measurements.

In the context of the present disclosure, a “digital signal parameter” means that the signal parameter is provided as a digital signal, i.e., as a discrete-value signal. The digital signal parameter may therefore be a symbol sequence, for example a bit sequence, which describes the value of the at least one signal parameter.

In an embodiment, the first measurement signal is a signal that has been processed by the device under test or reflected by the device under test. Fore example, the first measurement signal is the analog test signal which has been processed by the device under test or reflected by the device under test.

The test and/or measurement system according to the present disclosure is based on the basic idea of performing the frequency sweep in the digital domain instead of in the analog domain, as previously common in the prior art.

During the frequency sweep, the frequency of the analog test signal is adjusted step by step. After the individual adjustment steps, the test and/or measurement system according to the present disclosure does not require waiting for the settling time of an analog oscillator each time before measurements can be performed on the device under test. This significantly reduces the time required for the measurements.

As the first measurement circuit performs evaluation during the frequency sweep across the first frequency range with the unchanging first frequency conversion, there is no need to wait for settling times here either, which ensures fast evaluation of the analog test signal and the first measurement signal.

According to one aspect of the present disclosure, the at least one digital signal parameter, for example, comprises an amplitude of the analog test signal to be generated. Therefore, both the frequency and the amplitude can be adjusted in the digital domain, enabling precise control across the signal levels. It also enables consistent and accurate measurement results, as the digital adjustment of the frequency and amplitude is less susceptible to interference and provides precisely reproducible test conditions.

One aspect of the present disclosure provides, for example, that the first measurement circuit is set up to evaluate the portion of the analog test signal and the first measurement signal received via the first port during the frequency sweep across the first frequency band with unchanging amplification and/or unchanging attenuation. This ensures that all signal components are processed consistently during the frequency sweep, thereby improving the significance of the measurement results.

In an embodiment, the signal parameter circuit is further set up to successively adjust the frequency of the analog test signal across a second frequency band by the at least one generated digital signal parameter, so that the analog test signal has a frequency sweep across the second frequency band. The first measurement circuit may be set up to evaluate the portion of the analog test signal and the first measurement signal received via the first port during the frequency sweep across the second frequency band with an unchanging second frequency conversion. In this case, the first frequency conversion is different from the second frequency conversion. In other words, the frequency conversion thus respectively remains constant within the individual frequency bands, thereby achieving a time-optimized measurement within the frequency bands, as there is no need to wait for settling times. However, between measurements in the individual frequency bands, the frequency conversion is adjusted to ensure correct mixing into the baseband.

In general terms, the first frequency band and the second frequency band (and any other frequency bands) together cover a working range to be tested of the device under test.

In an embodiment, the first and second frequency bands can be adjacent to each other or partially overlap. However, it is also conceivable that the first and second frequency bands are disjoint, i.e., different from each other and without overlap.

In another embodiment of the present disclosure, the first measurement circuit comprises a first mixing circuit. The first mixing circuit is set up to respectively mix the portion of the analog test signal and the first measurement signal into a baseband by a local oscillator signal, wherein a frequency of the local oscillator signal is constant during a frequency sweep of the analog test signal. Accordingly, there is no need to wait for settling times of the local oscillator during the frequency sweep, as a result of which the measurements at the individual frequency points can be performed much more quickly.

According to one aspect of the present disclosure, the local oscillator signal, for example, has a different frequency during the frequency sweep across the first frequency band than during the frequency sweep across the second frequency band. This ensures that the portion of the analog test signal or the first measurement signal is always correctly mixed into the baseband.

A further aspect of the present disclosure provides, for example, that the test and/or measurement system has a second port. In an embodiment, the second port is connected to the signal generator circuit and is adapted to be connected to the device under test. The test and/or measurement system also has a second coupling circuit arranged between the signal generator circuit and the second port. The test and/or measurement system also has a second measurement circuit connected to the second coupling circuit, wherein the second measurement circuit has a second analog-to-digital converter and is set up to evaluate a portion of the analog test signal and a second measurement signal received via the second port. Transmission and/or reflection measurements can be performed on the device under test via the first port and the second port, wherein the analog test signal can be output to the device under test selectively via the first port and/or the second port.

For example, the first measurement signal may correspond to the analog test signal output via the first port and reflected by the device under test. In addition, the first measurement signal may correspond to the analog test signal output via the second port and processed by the device under test.

In an embodiment, the second measurement signal may correspond to the analog test signal output via the second port and reflected by the device under test. In addition, the second measurement signal may correspond to the analog test signal output via the first port and processed by the device under test.

In an embodiment, the second measurement circuit is set up to evaluate the portion of the analog test signal and the second measurement signal received via the second port during the frequency sweep across the first frequency band with an unchanging frequency conversion. Accordingly, there is no need to wait for settling times between the measurements at the individual frequency points, which significantly reduces the time required for the measurements.

In an embodiment, the frequency conversion performed by the second measurement circuit may be the same as the frequency conversion performed by the first measurement circuit. In an embodiment, the measurement circuits may receive the same local oscillator signal for the frequency conversion.

In an embodiment, the second measurement circuit may comprise a second mixing circuit, wherein the second mixing circuit is set up to respectively mix the portion of the analog test signal and the second measurement signal into a baseband by a local oscillator signal, wherein a frequency of the local oscillator signal is constant during a frequency sweep of the analog test signal. Accordingly, there is no need to wait for settling times of the local oscillator during the frequency sweep, which allows the measurements at the individual frequency points to be performed much faster.

According to one aspect of the present disclosure, the first mixing circuit and the second mixing circuit, for example, receive the same local oscillator signal. This ensures that the first measurement circuit and the second measurement circuit convert the portion of the analog test signal and the measurement signals based on the same local oscillator signal, thus ensuring consistent evaluation of the analog test signal and the measurement signals.

In an embodiment, the signal generator circuit has at least one digital-to-analog converter. The at least one digital-to-analog converter may be set up to output an analog baseband signal corresponding to the analog test signal. The analog baseband signal can then be mixed with a local oscillator signal to obtain the analog test signal.

However, it should be noted that further components may be provided, for example amplifiers for amplifying the analog test signal.

In another embodiment of the present disclosure, the signal generator circuit and the first measurement circuit receive the same local oscillator signal. Fewer different components are thus required, namely fewer local oscillators.

In an embodiment, the signal generator circuit, the first measurement circuit, and the second measurement circuit may receive the same local oscillator signal.

Alternatively, the signal generator circuit and the first measurement circuit may receive local oscillator signals which are different from each other. However, the first measurement circuit and the second measurement circuit receive the same local oscillator signal to ensure consistent evaluation of the first measurement signal, the second measurement signal, and the portion of the analog test signal.

According to one aspect of the present disclosure, the first coupling circuit, for example, has a power divider, wherein the signal generator circuit is connected to the first measurement circuit via the power divider. The portion of the analog test signal may be forwarded directly to the first measurement circuit via the power divider.

In an embodiment, the test and/or measurement system comprises a test and/or measurement device, wherein the signal parameter circuit, the signal generator circuit, the first port, the first coupling circuit, and the first measurement circuit are integrated into the test and/or measurement device. This provides a highly integrated test and/or measurement system which allows measurements to be taken on the device under test with minimal cabling.

In an embodiment, the other components of the test and/or measurement system described above may also be integrated into the test and/or measurement device, for example the second port, the second measurement circuit, and/or the second coupling circuit.

In an embodiment, the test and/or measurement device is a vector network analyzer or a signal analyzer. However, the test and/or measurement device may also be configured as any other suitable type of test and/or measurement device.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a test and/or measurement system according to an embodiment of the present disclosure;

FIG. 2 schematically shows an example of a test and/or measurement device of the test and/or measurement system of FIG. 1; and

FIG. 3 shows a representative diagram illustrating a measurement sequence.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

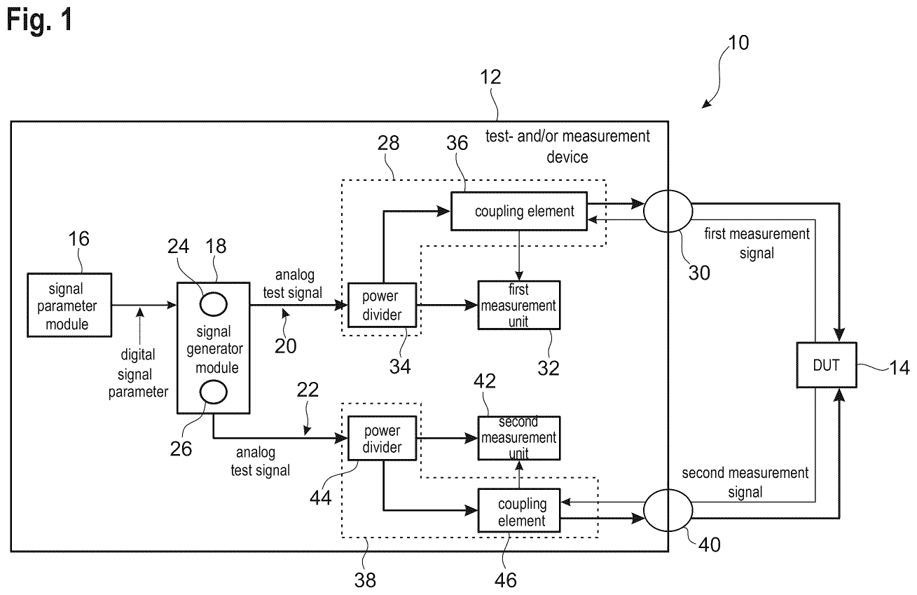

FIG. 1 schematically shows a test and/or measurement system 10 comprising a test and/or measurement device 12 and a device under test 14. In general terms, the test and/or measurement device 12 is set up to perform measurements on the device under test 14 to verify a correct functionality of the device under test.

The test and/or measurement device 12 is, for example, a vector network analyzer or a signal analyzer. However, the test and/or measurement device 12 may also be configured as any other suitable type of test and/or measurement device, for example as a spectrum analyzer or as an oscilloscope, for example as a digital oscilloscope.

The device under test 14 is an electronic device set up to process high-frequency signals. For example, the device under test 14 may be an amplifier, a mixer, a filter, a high-frequency front end, or a communication circuit.

In the embodiment of FIG. 1, the test and/or measurement device 12 comprises a signal parameter circuit 16 and a signal generator circuit 18, wherein the signal generator circuit 18 is connected downstream of the signal parameter circuit 16. The signal parameter circuit 16 is set up to provide at least one digital signal parameter and to transmit it to the signal generator circuit 18. The signal generator circuit 18 is set up to generate the analog test signal based on the at least one digital signal parameter.

The at least one digital signal parameter comprises at least one frequency of an analog test signal to be generated. In addition, the at least one digital signal parameter may comprise an amplitude of the analog test signal to be generated.

In the example embodiment shown in FIG. 1, the test and/or measurement device 12 has a first signal path 20 and a second signal path 22, both of which are connected to the signal generator circuit 18. The signal generator circuit 18 is set up to output the analog test signal selectively to the first signal path 20 and/or to the second signal path 22.

Optionally, the signal generator circuit 18 may have a first signal generator circuit 24 and a second signal generator circuit 26. The first signal generator circuit 24 may then be set up to generate the analog test signal and output it to the first signal path 20. The first signal generator circuit 24 may be set up to generate the analog test signal and output it to the first signal path 20. The second signal generator circuit 26 may be set up to generate the analog test signal and output it to the second signal path 22.

The test and/or measurement device 12 further has a first coupling circuit 28, a first port 30, and a first measurement circuit 32. The first coupling circuit 28 is set up to forward the analog test signal to both the first port 30 and the first measurement circuit 32.

In the example embodiment shown in FIG. 1, the first coupling circuit 28 comprises a first power divider 34, which is connected downstream of the signal generator circuit 18, and a first coupling element 36. The first power divider 34 is set up to forward a portion of the analog test signal to the first measurement circuit 32 and to forward the remaining portion of the analog test signal to the first coupling element 36.

Here and in the following, “portion of a signal” refers to a portion of the signal level. The “portion of the analog test signal” and the “remaining portion of the analog test signal” therefore correspond to the analog test signal in terms of frequency and phase, but each has only a certain proportion of the original signal level. Since the “remaining portion of the analog test signal” is identical to the analog test signal except for the level, the term “analog test signal” is simply used therefor in the following.

The first coupling element 36 is set up to forward the analog test signal to the first port 30. The first coupling element 36 is also set up to forward a first measurement signal received via the first port 30 to the first measurement circuit 32.

In an embodiment, the first coupling element 36 is, for example, a directional coupler. However, it should be noted that the first coupling circuit 28 may also be configured in any other suitable manner. For example, the first power divider 34 and the first coupling element 36 may be replaced by a directional coupler having four ports.

The test and/or measurement device 12 also has a second coupling circuit 38, a second port 40, and a second measurement circuit 42. The second coupling circuit 38 is set up to forward the analog test signal to both the second port 40 and the second measurement circuit 42.

In the example embodiment shown in FIG. 1, the second coupling circuit 38 comprises a second power divider 44, which is connected downstream of the signal generator circuit 18, and a second coupling element 46. The second power divider 44 is set up to forward a portion of the analog test signal to the second measurement circuit 42 and to forward the remaining portion of the analog test signal to the second coupling element 46.

The second coupling element 46 is set up to forward the analog test signal to the second port 40. The second coupling element 46 is further set up to forward a second measurement signal received via the second port 40 to the second measurement circuit 42.

In an embodiment, the second coupling element 46 is a directional coupler, for example. However, it should be noted that the second coupling circuit 38 may also be configured in any other suitable manner. For example, the second power divider 44 and the second coupling element 46 can be replaced by a four-port directional coupler.

In an embodiment, the first measurement signal and the second measurement signal each correspond to the analog test signal processed by the device under test 14 and/or reflected by the device under test 14. For example, the first measurement signal may correspond to the analog test signal output via the first port 30 and reflected by the device under test 14. Alternatively, the first measurement signal may correspond to the analog test signal output via the second port 40 and processed by the device under test 14.

In an embodiment, the second measurement signal may correspond to the analog test signal output via the second port 40 and reflected by the device under test 14. Alternatively, the second measurement signal may correspond to the analog test signal output via the first port 30 and processed by the device under test 14.

In an embodiment, the first measurement circuit 32 and the second measurement circuit 42 are set up to analyze the first and the second measurement signal, respectively, as a result of which at least one performance parameter is obtained.

In general, the at least one performance parameter is a measure of the correct functionality of the device under test 14. The at least one performance parameter may, for example, comprise scattering parameters of the device under test 14, for example S-parameters of the device under test 14. However, the at least one performance parameter may also comprise any other suitable parameter.

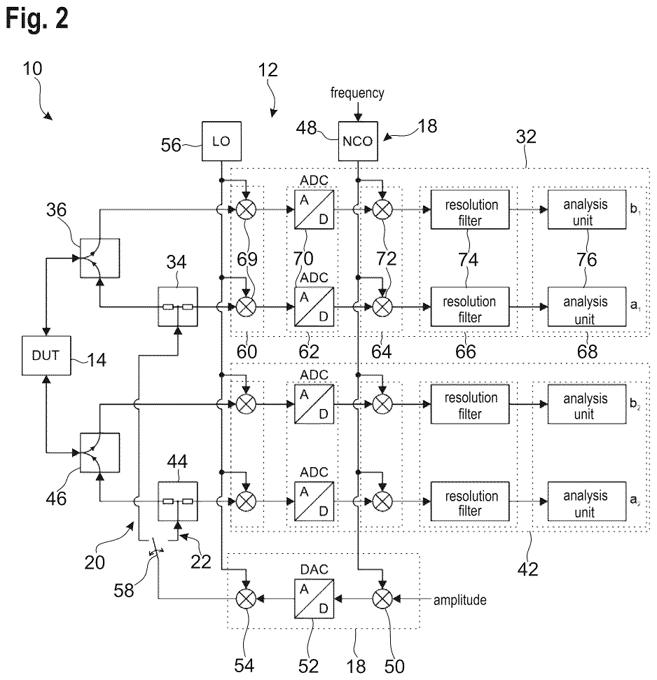

FIG. 2 schematically shows a more detailed view of a part of the test and/or measurement system 10 described above. As shown in FIG. 2, the signal generator circuit 18 may comprise a signal generator circuit 48 which is configured, for example, as a numerically controlled oscillator (NCO). The signal generator circuit 48 receives the frequency of the analog test signal to be generated from the signal parameter circuit 16 and generates a digital frequency signal with a matching frequency.

In an embodiment, the signal generator circuit 18 also comprises a digital mixing circuit 50, which is connected to the signal generator circuit 48. The digital mixing circuit 50 receives the digital frequency signal from the signal generator circuit 48 and a digital amplitude signal from the signal parameter circuit 16. The digital mixing circuit 50 is set up to mix the digital frequency signal with the digital amplitude signal, thereby obtaining a digital baseband test signal.

In an embodiment, the signal generator circuit 18 further comprises a digital-to-analog converter 52 which is set up to convert the digital baseband test signal into an analog baseband test signal. The signal generator circuit 18 further comprises an analog mixing circuit 54 which is connected to a local oscillator 56.

In an embodiment, the local oscillator 56 may be integrated into the test and/or measurement device 12. Alternatively, the local oscillator 56 may be provided outside the test and/or measurement device 12. In this case, the test and/or measurement device 12 may have an input for the local oscillator signal.

In an embodiment, the analog mixing circuit 54 is set up to mix the analog baseband test signal with a local oscillator signal provided by the local oscillator 56, thereby obtaining the analog test signal.

In the example embodiment of FIG. 2, the test and/or measurement device includes a switching circuit 58 that is set up to selectively output the analog test signal to the first signal path 20 or to the second signal path 22.

The first measurement circuit 32 comprises a first analog mixing circuit 60, a first converter circuit 62, a first digital mixing circuit 64, a first filter circuit 66, and a first analysis circuit 68. The first analog mixing circuit 60 is set up to mix the analog test signal and the first measurement signal into the baseband, more specifically based on the local oscillator signal of the local oscillator 56.

It should be noted that it is also conceivable that the signal generator circuit 18 and the first measurement circuit 32 receive local oscillator signals which are different from each other.

For example, the first analog mixing circuit 60 has two first analog mixing circuits 69 that are set up to mix the analog test signal and the first measurement signal, respectively, with the local oscillator signal and thus convert them to the baseband.

In an embodiment, the first converter circuit 62 is set up to respectively convert the analog test signal mixed into the baseband and the first measurement signal mixed into the baseband into a digital signal, a digitized test signal and a digitized first measurement signal being thus obtained. For this purpose, the first converter circuit 62 has two analog-to-digital converters 70.

In an embodiment, the first digital mixing circuit 64 is set up to mix the digitized test signal and the digitized first measurement signal with the frequency signal provided by the signal generator circuit 48. For example, the first digital mixing circuit 64 has two first digital mixing circuits 72, which are set up to mix the digitized test signal and the first digitized measurement signal with the frequency signal.

In an embodiment, the digitized test signal and the digitized first measurement signal can be filtered by the first filter circuit 66, for example by two resolution filters 74. The resolution filters 74 define a bandwidth with which the digitized test signal and the digitized first measurement signal are evaluated. The bandwidth of the resolution filters 74 can be adjustable.

In an embodiment, the digitized test signal and the digitized first measurement signal are then evaluated by the first analysis circuit 68, namely by two analysis circuits 76. Waveform parameters a_1 and b_1 are thus obtained, which describe the analog test signal and the first measurement signal, respectively.

In an embodiment, the second measurement circuit 42 is constructed analogously to the first measurement circuit 32, which is why reference is made to the above explanations as to the first measurement circuit 32 with regard to the exact structure of the second measurement circuit 42.

In an embodiment, the second measurement circuit 42 processes the analog test signal and the second measurement signal, the waveform parameters a_2 and b_2 being thus obtained. The power parameters of the device under test 14 described above can then be determined from the waveform parameters.

The test and/or measurement system 10, or more precisely the test and/or measurement device 12, has a measurement operating mode in which a frequency sweep of the analog test signal is performed. Here, the signal parameter circuit 16 adjusts the at least one digital signal parameter, or more precisely the frequency, step by step so that the digital frequency signal generated by the signal generator circuit 48 has a defined frequency sweep.

In an embodiment, the defined frequency sweep is selected such that the analog test signal generated based on the digital frequency signal has a frequency sweep across a first frequency band. A measurement of the waveform parameters a_i and b_i is performed for each frequency point of the frequency sweep.

The bandwidth of the frequency sweep, i.e., the bandwidth of the first frequency band, depends on the maximum bandwidth of the digital-to-analog converter 52 and the maximum bandwidth of the analog-to-digital converters 70. In an embodiment, the first frequency band covers, for example, frequencies up to 500 MHz, up to 1000 MHz, up to 1500 MHz, up to 2000 MHz, or higher.

During the frequency sweep across the first frequency band, the frequency of the local oscillator signal remains unchanged, so that no settling times of the local oscillator 56 need to be waited for between the individual measurement points.

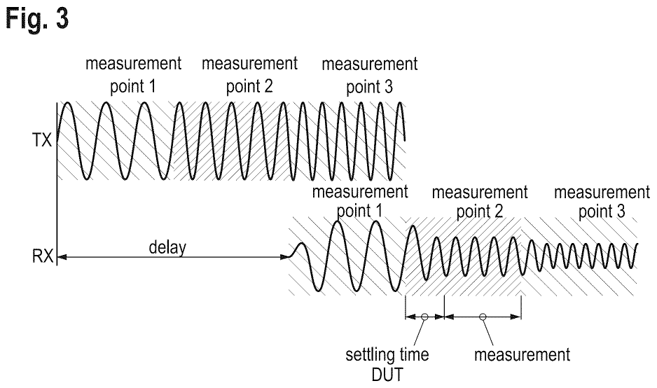

The measurement sequence is illustrated in FIG. 3. The upper part of FIG. 3 (“TX”) shows an example of the generated digital frequency signal for three consecutive measurement points. As can be clearly seen, no settling time is waited for. Instead, the frequency of the digital frequency signal is adjusted immediately between the measurement points.

The lower part of FIG. 3 (“RX”) shows that the measurement circuits 32, 42 only receive the corresponding signals after a delay caused by signal lines in the test and/or measurement device 12, by the device under test 14, and by cabling between the test and/or measurement device 12 and the device under test 14.

Furthermore, the lower part of FIG. 3 illustrates by way of example for the second measurement point, that it may be necessary to wait for a settling time of the device under test 14 before the respective measurement point is recorded.

After the frequency sweep across the first frequency band is complete, a frequency sweep across a second frequency band can be performed. In an embodiment, the first and second frequency bands may be adjacent to each other or may partially overlap. However, it is also conceivable that the first and second frequency bands are disjoint, i.e., different from each other and without overlap.

In addition, after the frequency sweep across the first frequency band and before the frequency sweep across the second frequency band, the frequency of the local oscillator signal can be adjusted accordingly.

During the frequency sweep across the second frequency band, however, the frequency of the local oscillator signal remains constant again.

In general, the evaluation of the analog test signal and the measurement signals during a frequency sweep is therefore performed with unchanging frequency conversion, i.e., with a constant frequency of the local oscillator signal. In addition, amplification and/or attenuation by the measurement circuits 32, 42 can be constant during a frequency sweep.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be used synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components of the test and/or measurement system 10, etc., referenced above include circuitry programmed to carry out one or more steps or actions of any of the methods disclosed herein. In an embodiment, one or more computer-readable media associated with or accessible by such circuitry contains computer readable instructions embodied thereon that, when executed by such circuitry, cause the component or circuitry to perform one or more steps or actions of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuitry disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. While the stated range includes one or both of the limits, ranges excluding either or both of those included limits are also included in the disclosure

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A test and/or measurement system for performing tests and/or measurements on a device under test,
wherein the test and/or measurement system comprises a signal parameter circuit which is set up to provide at least one digital signal parameter, wherein the at least one digital signal parameter comprises a frequency of an analog test signal to be generated,
wherein the test and/or measurement system comprises a signal generator circuit connected to the signal parameter circuit, wherein the signal generator circuit is set up to generate the analog test signal based on the at least one digital signal parameter,
wherein the test and/or measurement system has at least one first port, wherein the first port is connected to the signal generator circuit, wherein the first port is adapted to be connected to the device under test,
wherein the test and/or measurement system comprises a first coupling circuit arranged between the signal generator circuit and the first port,
wherein the test and/or measurement system comprises a first measurement circuit, wherein the first measurement circuit is connected to the first coupling circuit, wherein the first measurement circuit has a first analog-to-digital converter, and wherein the first measurement circuit is set up to evaluate a portion of the analog test signal and a first measurement signal received via the first port,
wherein the signal parameter circuit is set up to successively adjust the frequency of the analog test signal across a first frequency band by the at least one generated digital signal parameter, so that the analog test signal has a frequency sweep across the first frequency band, and
wherein the first measurement circuit is set up to evaluate the portion of the analog test signal and the first measurement signal received via the first port during the frequency sweep across the first frequency band with an unchanging first frequency conversion.

2. The test and/or measurement system according to claim 1, wherein the at least one digital signal parameter comprises an amplitude of the analog test signal to be generated.

3. The test and/or measurement system according to claim 1, wherein the first measurement circuit is set up to evaluate the portion of the analog test signal and the first measurement signal received via the first port during the frequency sweep across the first frequency band with unchanging amplification and/or unchanging attenuation.

4. The test and/or measurement system according to claim 1, wherein the signal parameter circuit is further set up to successively adjust the frequency of the analog test signal across a second frequency band by the at least one generated digital signal parameter, so that the analog test signal has a frequency sweep across the second frequency band, wherein the first measurement circuit is set up to evaluate the portion of the analog test signal and the first measurement signal received via the first port during the frequency sweep across the second frequency band with an unchanging second frequency conversion, wherein the first frequency conversion is different from the second frequency conversion.

5. The test and/or measurement system according to claim 1, wherein the first measurement circuit comprises a first mixing circuit, wherein the first mixing circuit is set up to respectively mix the portion of the analog test signal and the first measurement signal into a baseband by a local oscillator signal, wherein a frequency of the local oscillator signal is constant during a frequency sweep of the analog test signal.

6. The test and/or measurement system according to claim 4, wherein the first measurement circuit comprises a first mixing circuit, wherein the first mixing circuit is set up to respectively mix the portion of the analog test signal and the first measurement signal into a baseband by a local oscillator signal, wherein a frequency of the local oscillator signal is constant during a frequency sweep of the analog test signal, wherein the local oscillator signal has a different frequency during the frequency sweep across the first frequency band than during the frequency sweep across the second frequency band.

7. The test and/or measurement system according to claim 1, wherein the test and/or measurement system has a second port, wherein the second port is connected to the signal generator circuit, wherein the second port is adapted to be connected to the device under test,
wherein the test and/or measurement system has a second coupling circuit arranged between the signal generator circuit and the second port,
wherein the test and/or measurement system comprises a second measurement circuit, wherein the second measurement circuit is connected to the second coupling circuit, wherein the second measurement circuit has a second analog-to-digital converter, and wherein the second measurement circuit is set up to evaluate a portion of the analog test signal and a second measurement signal received via the second port.

8. The test and/or measurement system according to claim 7, wherein the second measurement circuit is set up to evaluate the portion of the analog test signal and the second measurement signal received via the second port during the frequency sweep across the first frequency band with an unchanging frequency conversion.

9. The test and/or measurement system according to claim 8, wherein the second measurement circuit comprises a second mixing circuit, wherein the second mixing circuit is set up to respectively mix the portion of the analog test signal and the second measurement signal into a baseband by a local oscillator signal, wherein a frequency of the local oscillator signal is constant during a frequency sweep of the analog test signal.

10. The test and/or measurement system according to claim 9, wherein the first measurement circuit comprises a first mixing circuit, wherein the first mixing circuit is set up to respectively mix the portion of the analog test signal and the first measurement signal into a baseband by a local oscillator signal, wherein a frequency of the local oscillator signal is constant during a frequency sweep of the analog test signal, wherein the first mixing circuit and the second mixing circuit receive the same local oscillator signal.

11. The test and/or measurement system according to claim 1, wherein the signal generator circuit has at least one digital-to-analog converter.

12. The test and/or measurement system according to claim 1, wherein the signal generator circuit and the first measurement circuit receive the same local oscillator signal.

13. The test and/or measurement system according to claim 1, wherein the signal generator circuit and the first measurement circuit receive local oscillator signals which are different from each other.

14. The test and/or measurement system according to claim 1, wherein the first coupling circuit has a power divider, wherein the signal generator circuit is connected to the first measurement circuit via the power divider.

15. The test and/or measurement system according to claim 1, wherein the test and/or measurement system comprises a test and/or measurement device, wherein the signal parameter circuit, the signal generator circuit, the first port, the first coupling circuit, and the first measurement circuit are integrated into the test and/or measurement device.

16. The test and/or measurement system according to claim 15, wherein the test and/or measurement device is a vector network analyzer or a signal analyzer.
